(19) United States
(12) Patent Application Publication
(10) Pub. No.: US 2018/0175190 A1
(43) Pub. Date: Jun. 21, 2018

(54) VERTICAL DOUBLE DIFFUSION METAL-OXIDE-SEMICONDUCTOR POWER DEVICE WITH HIGH VOLTAGE START-UP UNIT

(71) Applicant: Leadtrend Technology Corp., Hsinchu County (TW)

(72) Inventor: Jen-Hao Yeh, Hsinchu County (TW)

(21) Appl. No.: 15/842,845

(22) Filed: Dec. 14, 2017

Related U.S. Application Data
(60) Provisional application No. 62/435,086, filed on Dec. 16, 2016.

(51) Int. Cl. H01L 29/78; H01L 29/06; H01L 21/762; H01L 21/265

(52) U.S. Cl. CPC H01L 29/7815; H01L 29/7803; H01L 21/26513; H01L 29/0649; H01L 21/76202; H01L 29/7811

(57) ABSTRACT

A vertical double diffusion metal-oxide-semiconductor power device with high voltage start-up unit includes a vertical double diffusion metal-oxide-semiconductor power transistor and the high voltage start-up unit. The vertical double diffusion metal-oxide-semiconductor power transistor includes a first metal layer, a substrate layer with first conductivity type, an epitaxy layer with first conductivity type, a second metal layer, and a plurality of polysilicon layers. The substrate layer is formed on the first metal layer. The epitaxy layer is formed on the substrate layer. The plurality of polysilicon layers are formed on the epitaxy layer. The second metal layer is formed on the plurality of polysilicon layers and the epitaxy layer. The high voltage start-up unit is formed on the epitaxy layer, wherein the high voltage start-up unit is used for providing a two-dimensional direction start-up current to the vertical double diffusion metal-oxide-semiconductor power device.

### CROSS REFERENCE TO RELATED APPLICATIONS

This application claims the benefit of U.S. Provisional Application No. 62/435,086, filed on Dec. 16, 2016 and entitled “Power Semiconductor Devices Embedded HV Start-up Cells,” the contents of which are incorporated herein by reference.

### BACKGROUND OF THE INVENTION

### 1. Field of the Invention

The present invention relates to a vertical double diffused metal-oxide-semiconductor (VDMOS) power device, and particularly to a VDMOS power device with high voltage start-up unit.

### 2. Description of the Prior Art

In the prior art, when an integrated circuit is powered on, a high voltage start-up unit included in the integrated circuit can generate a start-up current to charge a predetermined capacitor, wherein the predetermined capacitor can generate a start-up voltage to start up other function units of the integrated circuit according to the start-up current. However, because the start-up current is small, it will take more time for the predetermined capacitor to generate the start-up voltage, that is to say, the integrated circuit may need to take a long period of time to work normally, or the integrated circuit fails to start up because the start-up voltage is generated too late. Therefore, how to increase the start-up current provided by the prior art becomes an important issue.

### SUMMARY OF THE INVENTION

An embodiment of the present invention provides a vertical double diffused metal-oxide-semiconductor (VDMOS) power device with high voltage start-up unit. The VDMOS power device includes a VDMOS power transistor and the high voltage start-up unit. The VDMOS power transistor includes a first metal layer, a substrate layer with first conductivity type, an epitaxy layer with first conductivity type, a second metal layer, and a plurality of polysilicon layers. The substrate layer is formed on the first metal layer. The epitaxy layer is formed on the substrate layer. The plurality of polysilicon layers are formed on the epitaxy layer, wherein the second metal layer is formed on the plurality of polysilicon layers and the epitaxy layer. The high voltage start-up unit is formed on the epitaxy layer, wherein the high voltage start-up unit is used for providing a two-dimensional direction start-up current to the VDMOS power device.

The present invention provides a VDMOS power device. The VDMOS power device utilizes a same process to integrate a VDMOS power transistor included in the VDMOS power device with a high voltage start-up unit included in the VDMOS power device, wherein the high voltage start-up unit can provide a two-dimensional direction start-up current to predetermined function units of the VDMOS power device. Because the high voltage start-up unit can adjust and provide the two-dimensional direction start-up current in a two-dimensional direction, compared to the prior art, the high voltage start-up unit not only has a greater flexibility to adjust the two-dimensional direction start-up current, but can also provide the greater two-dimensional direction start-up current. Therefore, the present invention not only can make the VDMOS power device normally work in a shorter period of time after the VDMOS power device is powered on, but cannot also make the VDMOS power device fail to start up.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a cross section of a vertical double diffused metal-oxide-semiconductor (VDMOS) power device with high voltage start-up unit according to a first embodiment of the present invention.

FIG. 2 is a diagram illustrating a top view corresponding to FIG. 1.

FIG. 3 is a diagram illustrating a top view of the VDMOS power device.

FIG. 4 is a diagram illustrating an equivalent circuit corresponding to FIG. 1.

FIGS. 5-8 are diagrams illustrating top views of the VDMOS power device according to different embodiments of the present invention.

FIG. 9 is a diagram illustrating a top view of a VDMOS power device with high voltage start-up unit according to a second embodiment of the present invention.

FIG. 10 is a diagram illustrating a cross section of a VDMOS power device with high voltage start-up unit according to a third embodiment of the present invention.

FIG. 11 is a diagram illustrating a top view corresponding to FIG. 10.

FIG. 12 is a diagram illustrating an equivalent circuit corresponding to FIG. 10.

FIGS. 13-16 are diagrams illustrating top views of the VDMOS power device according to different embodiments of the present invention.

FIG. 17 is a diagram illustrating a top view of a VDMOS power device with high voltage start-up unit according to a fourth embodiment of the present invention.

### DETAILED DESCRIPTION

Please refer to FIG. 1. FIG. 1 is a diagram illustrating a cross section of a vertical double diffused metal-oxide-semiconductor (VDMOS) power device 100 with high voltage start-up unit according to a first embodiment of the present invention. As shown in FIG. 1, the VDMOS power device 100 includes a VDMOS power transistor 102 and a high voltage start-up unit 104, wherein the high voltage start-up unit 104 is a junction field effect transistor (JFET). But, the present invention is not limited to the VDMOS power device 100 including one VDMOS power transistor, that is, the VDMOS power device 100 can include more than one VDMOS power transistor. As shown in FIG. 1, the VDMOS power transistor 102 includes a first metal layer 1022, a substrate layer 1024 with first conductivity type, an epitaxy layer 1026 with first conductivity type, a second metal layer 1028, and a polysilicon layer 1030 of a plurality of polysilicon layers. As shown in FIG. 1, the substrate layer 1024 is formed on the first metal layer 1022. The epitaxy layer 1026 is formed on the substrate layer 1024. The polysilicon layer 1030 corresponds to a first oxide layer 1032, a first doping well 1034 and a second doping well 1036 with second conductivity type, a first doping region 1038 and a second doping region 1040 with first conductivity type, and a second oxide layer 1042, wherein the first oxide layer 1032 is formed on the epitaxy layer 1026, the first doping well 1034 and the second doping well 1036 are formed within the epitaxy layer 1026, the first doping region 1038 and the second doping region 1040 are formed within the first doping well 1034 and the second doping well 1036 respectively, the polysilicon layer 1030 is formed on the first oxide layer 1032, the second oxide layer 1042 covers the polysilicon layer 1030, and the second metal layer 1028 is formed on the first doping well 1034, the second doping well 1036, the first doping region 1038, the second doping region 1040, and the second oxide layer 1042. In addition, the first conductivity type is N type and the second conductivity type is P type, and ion concentration of the substrate layer 1024 is greater than ion concentration of the epitaxy layer 1026.

As shown in FIG. 1, the first metal layer 1022 is a drain of the VDMOS power transistor 102, the plurality of polysilicon layers are a gate of the VDMOS power transistor 102, and the second metal layer 1028 is a source of the VDMOS power transistor 102. Therefore, when the VDMOS power transistor 102 is turned on, a current 1044 flows from the first metal layer 1022 (the drain of the VDMOS power transistor 102) through the substrate layer 1024, the epitaxy layer 1026, channels 1046, 1048, and the first doping region 1038 and the second doping region 1040 to the second metal layer 1028 (the source of the VDMOS power transistor 102). In addition, the VDMOS power transistor 102 utilizes a depletion region (not shown in FIG. 1) formed by a PN junction between the first doping well 1034 and the epitaxy layer 1026 and a depletion region (not shown in FIG. 1) formed by a PN junction between the second doping well 1036 and the epitaxy layer 1026 to endure a voltage between the drain and the source of the VDMOS power transistor 102.

As shown in FIG. 1, the high voltage start-up unit 104 includes a deep doping well 1041 with second conductivity type, a doping region 1043 with first conductivity type, a gate 1045, and a source 1047, wherein the deep doping well 1041 is formed within the epitaxy layer 1026, the doping region 1043 is formed within the deep doping well 1041, and the gate 1045 and the source 1047 of the high voltage start-up unit 104 are formed on the deep doping well 1041, wherein the source 1047 of the high voltage start-up unit 104 is electrically connected to the doping region 1043 through a contact 1049, the gate 1045 of the high voltage start-up unit 104 is electrically connected to the deep doping well 1041 through a contact 1051, and the deep doping well 1041 surrounds a well 1053. In addition, as shown in FIG. 1, the VDMOS power device 100 further includes a field oxide layer 1058, wherein the field oxide layer 1058 is formed on the epitaxy layer 1026 and between the VDMOS power transistor 102 and the high voltage start-up unit 104, the field oxide layer 1058 is used for making the VDMOS power transistor 102 be isolated from the high voltage start-up unit 104, and the field oxide layer 1058 is formed through a Local Oxidation of Silicon (LOCOS) method.

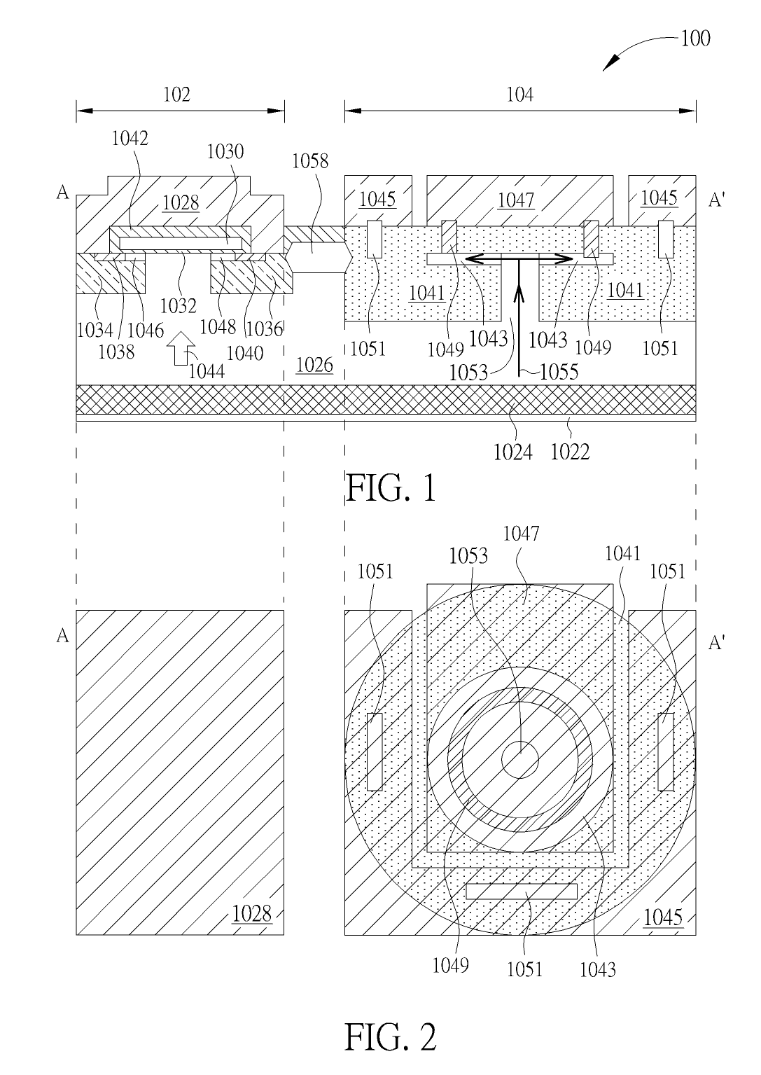

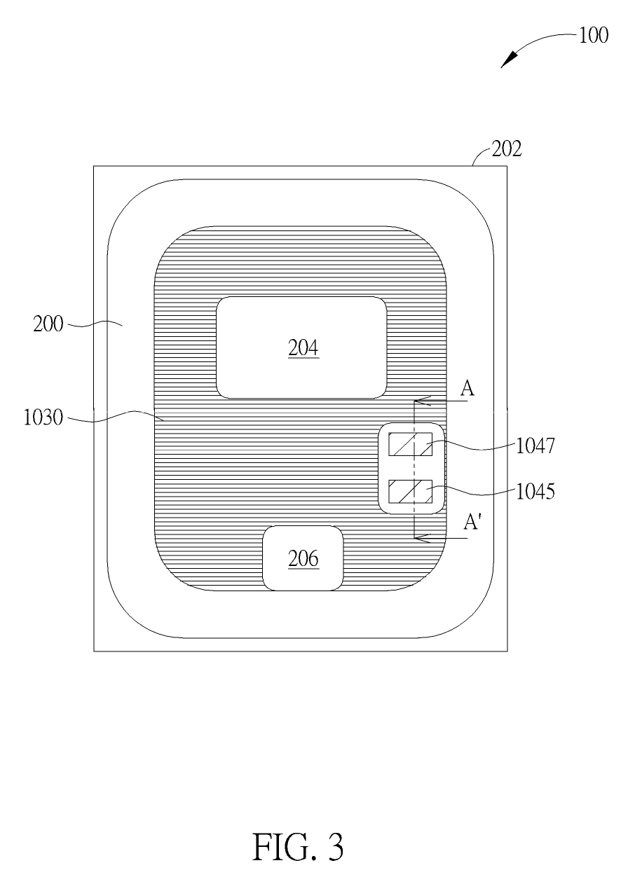

Please refer to FIG. 2. FIG. 2 is a diagram illustrating a top view corresponding to FIG. 1, and FIG. 3 is a diagram illustrating a top view of the VDMOS power device 100, wherein FIG. 1 corresponds to a straight line AA′ shown in FIG. 3. As shown in FIG. 2, the doping region 1043 has a two-dimensional shape in a top view of the VDMOS power device 100. That is to say, the two-dimensional shape of the doping region 1043 corresponds to a first concentric circle centered on the well 1053 in the top view of the VDMOS power device 100. Therefore, as shown in FIG. 2, when the VDMOS power device 100 is powered on, the high voltage start-up unit 104 can provide a two-dimensional direction start-up current 1055 (from the first metal layer 1022 through the epitaxy layer 1026, the well 1053, and the doping region 1043 to the source 1047) to the VDMOS power device 100 to wake up predetermined function units (not shown in FIG. 1) of the VDMOS power device 100, wherein the high voltage start-up unit 104 can control the two-dimensional direction start-up current 1055 through the gate 1045. Because the high voltage start-up unit 104 is a junction field effect transistor, operational principles of the high voltage start-up unit 104 are similar to those of a depletion metal-oxide-semiconductor transistor, that is, a negative voltage is applied to the gate 1045 to adjust a depletion region corresponding to the doping region 1043 to change the two-dimensional direction start-up current 1055. In addition, as shown in FIG. 3, the VDMOS power device 100 further includes an isolation region 200 for surrounding the VDMOS power transistor 102 and the high voltage start-up unit 104 shown in FIG. 1, wherein the isolation region 200 can share a same mask with the deep doping well 1041. In addition, as shown in FIG. 3, a seal ring 202 surrounds the isolation region 200, wherein the seal ring 202 has a shielding effect of electromagnetic interference (EMI) and a function of isolating noise outside the VDMOS power device 100. In addition, FIG. 3 also shows a pad 204 corresponds to the source of the VDMOS power transistor 102 and a pad 206 corresponds to the gate of the VDMOS power transistor 102. In addition, the substrate layer 1024, the epitaxy layer 1026, the first doping well 1034, the second doping well 1036, the first doping region 1038, the second doping region 1040, the deep doping well 1041, and the doping region 1043 are formed through an ion implantation method. In addition, the VDMOS power device 100 further includes a passivation layer (not shown in FIG. 1) formed on the second metal layer 1028, the gate 1045, the deep doping well 1041, and the source 1047.

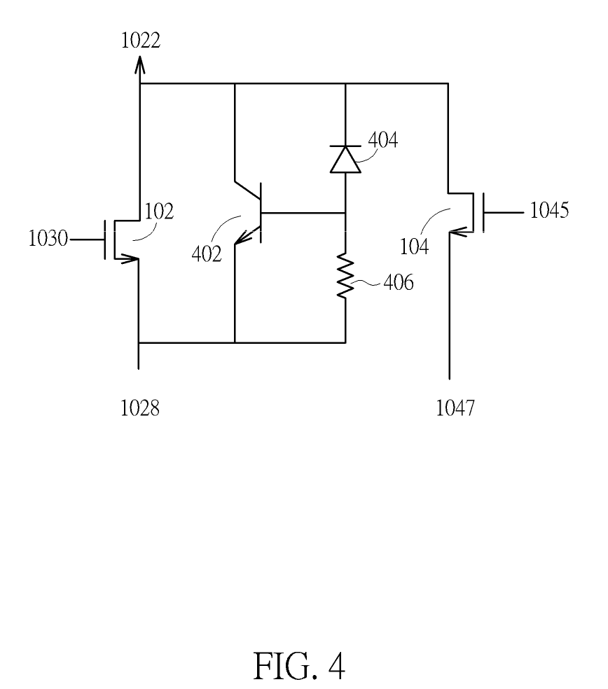

Please refer to FIG. 4. FIG. 4 is a diagram illustrating an equivalent circuit corresponding to FIG. 1. As shown in FIG. 4, the first metal layer 1022 is the drain of the VDMOS power transistor 102, the polysilicon layer 1030 (the plurality of polysilicon layers) is the gate of the VDMOS power transistor 102, and the second metal layer 1028 is the source of the VDMOS power transistor 102. An NPN type bipolar transistor 402 (composed of the first doping region 1038, the first doping well 1034, and the epitaxy layer 1026, or composed of the second doping region 1040, the second doping well 1036, and the epitaxy layer 1026) is electrically connected to the VDMOS power transistor 102 in parallel. In addition, a base of the NPN type bipolar transistor 402 is electrically connected to a diode 404 (composed of the first doping well 1034 and the epitaxy layer 1026, or composed of the second doping well 1036 and the epitaxy layer 1026) and an internal resistor 406 of the first doping well 1034 (or an internal resistor of the second doping well 1036). In addition, the first metal layer 1022 acts as a drain of the high voltage start-up unit 104 and the drain of the VDMOS power transistor 102.

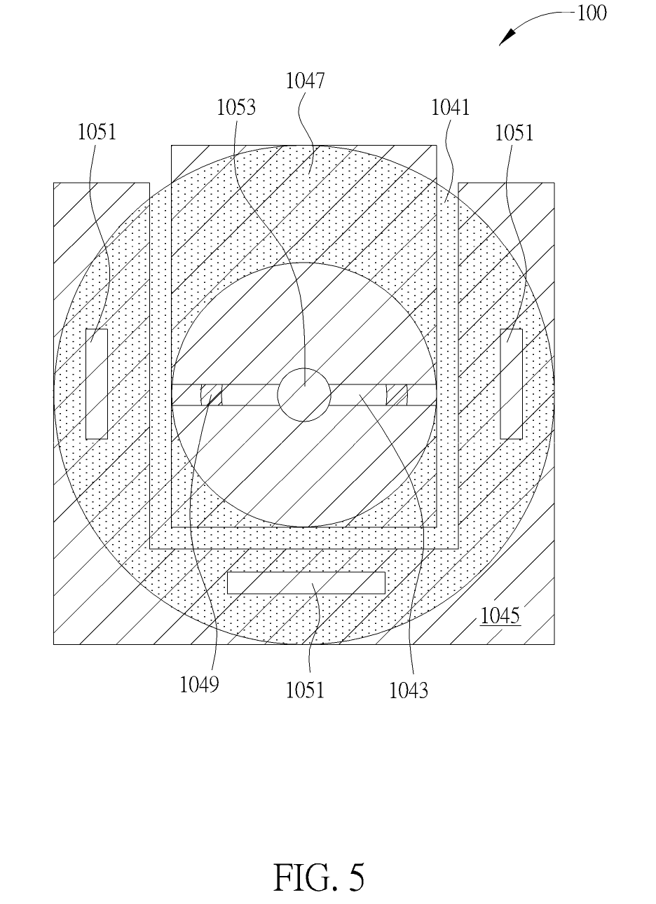

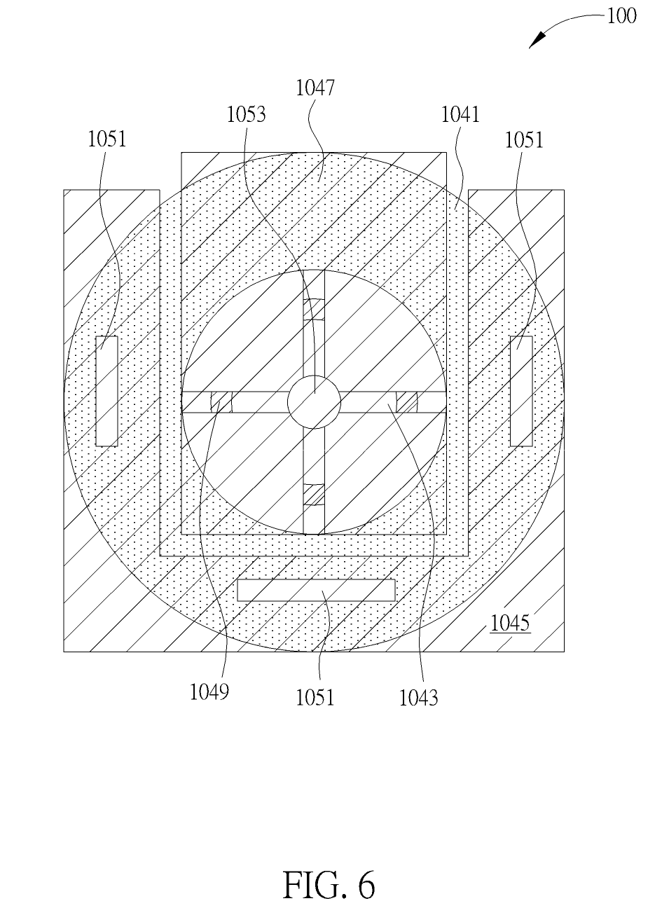

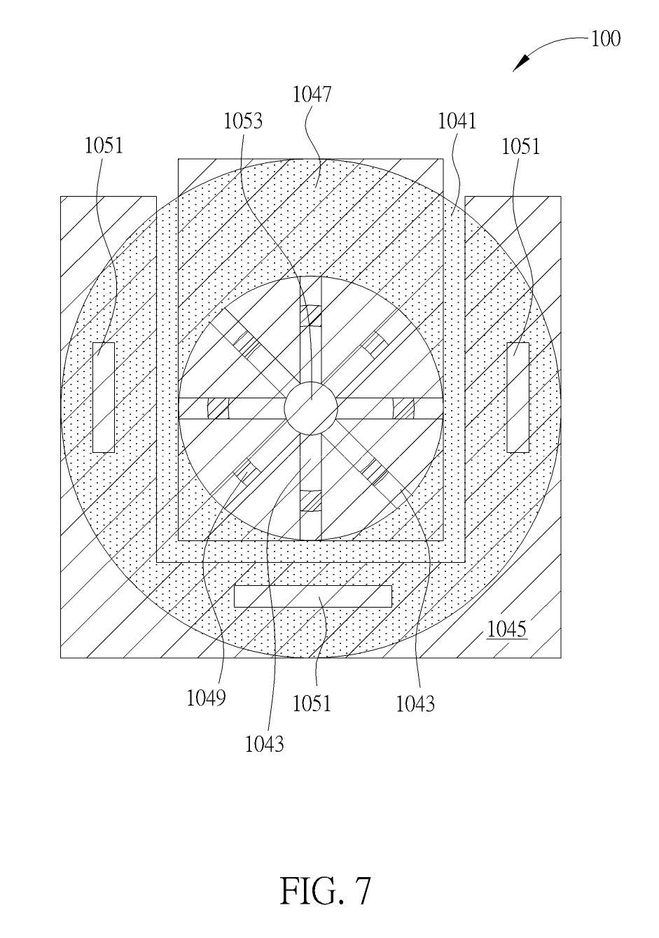

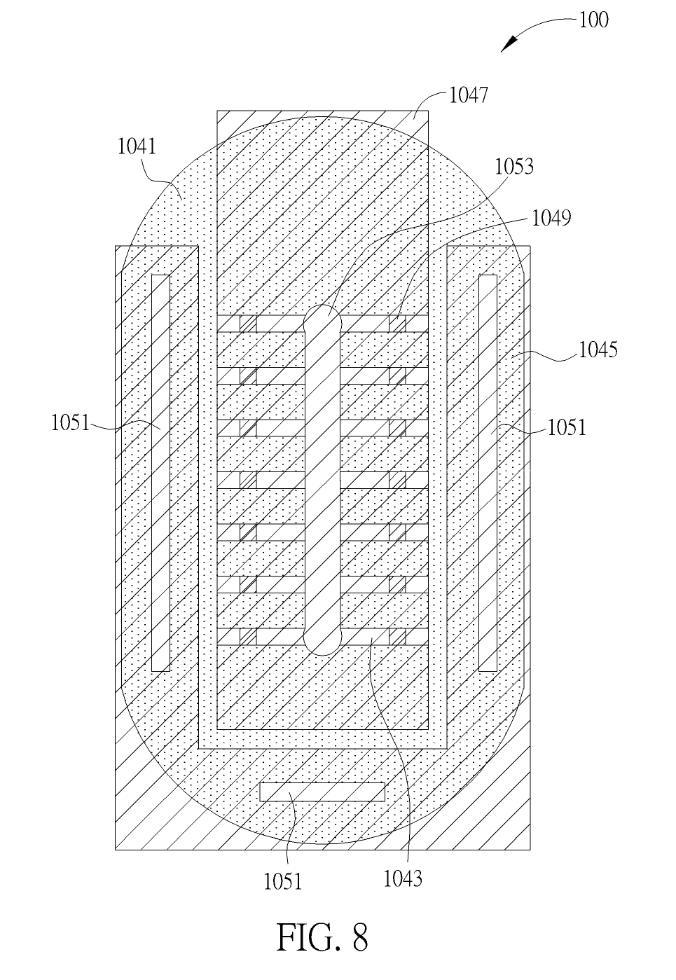

Please refer to FIGS. 5-8. FIGS. 5-8 are diagrams illustrating top views of the VDMOS power device 100 according to different embodiments of the present invention. As shown in FIGS. 5-7, the two-dimensional shape of the doping region 1043 corresponds to a plurality of channels centered on the well 1053. For example, in FIG. 5, the two-dimensional shape of the doping region 1043 corresponds to two channels centered on the well 1053, in FIG. 6, the two-dimensional shape of the doping region 1043 corresponds to fourth channels centered on the well 1053, and in FIG. 7, the two-dimensional shape of the doping region 1043 corresponds to eight channels centered on the well 1053. In addition, as shown in FIG. 8, a two-dimensional shape of the well 1053 corresponds to a strip, and the two-dimensional shape of the doping region 1043 corresponds to a plurality of first channels centered on the well 1053 (e.g. 14 first parallel channels centered on the well 1053).

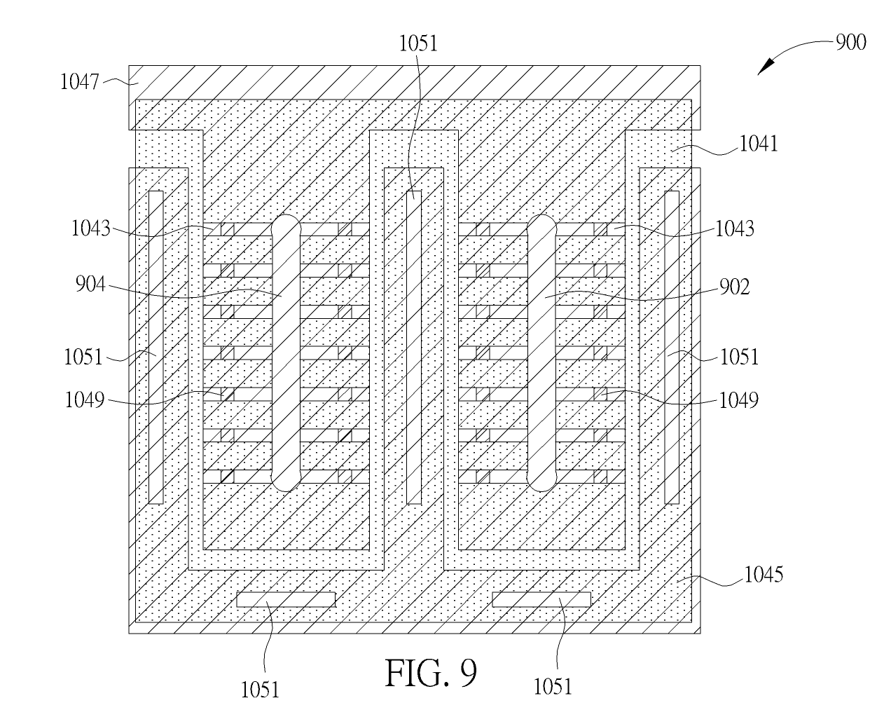

Please refer to FIG. 9. FIG. 9 is a diagram illustrating a top view of a VDMOS power device 900 with high voltage start-up unit according to a second embodiment of the present invention. As shown in FIG. 9, differences between the VDMOS power device 900 and the VDMOS power device 100 are that the deep doping well 1041 of the VDMOS power device 900 surround a plurality of wells (e.g. parallel wells 902, 904), a two-dimensional shape of each well of the plurality of wells corresponds to a strip, and the two-dimensional shape of the doping region 1043 of the VDMOS power device 900 corresponds to a plurality of first channels centered on the each well of the plurality of wells. For example, taking the well 902 as an example, the two-dimensional shape of the doping region 1043 of the VDMOS power device 900 corresponds to a plurality of first channels centered on the well 902 (e.g. 14 first parallel channels centered on the well 902). In addition, a number of the plurality of wells depends on a requirement of a designer of the VDMOS power device 900.

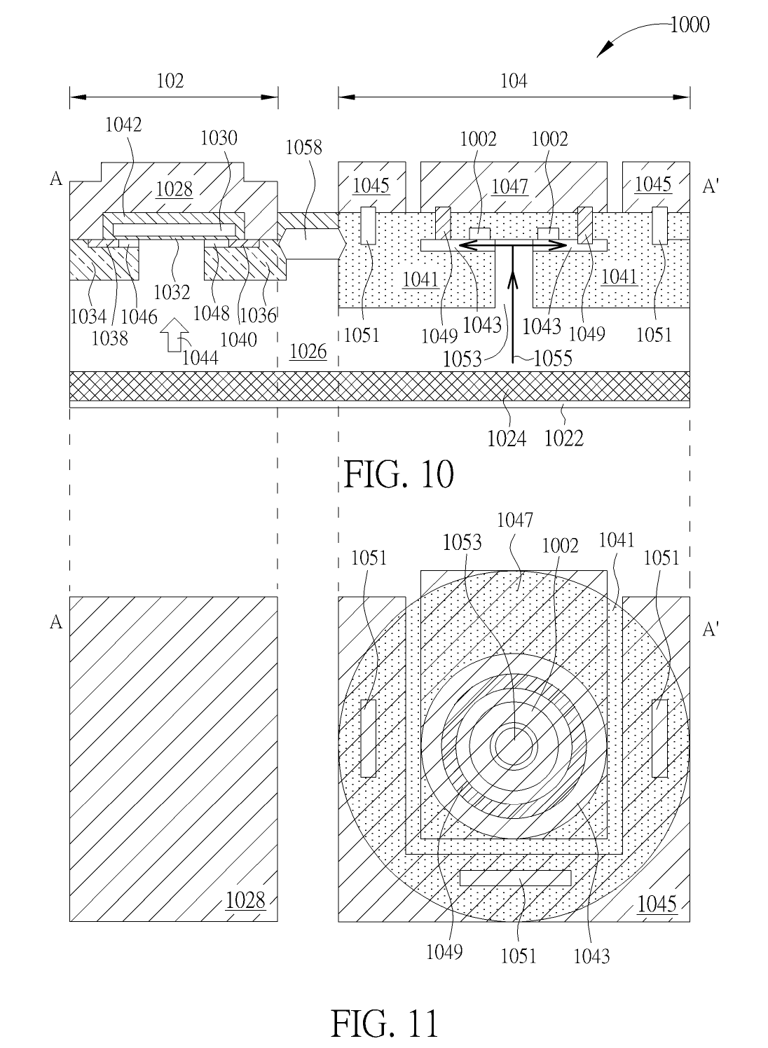

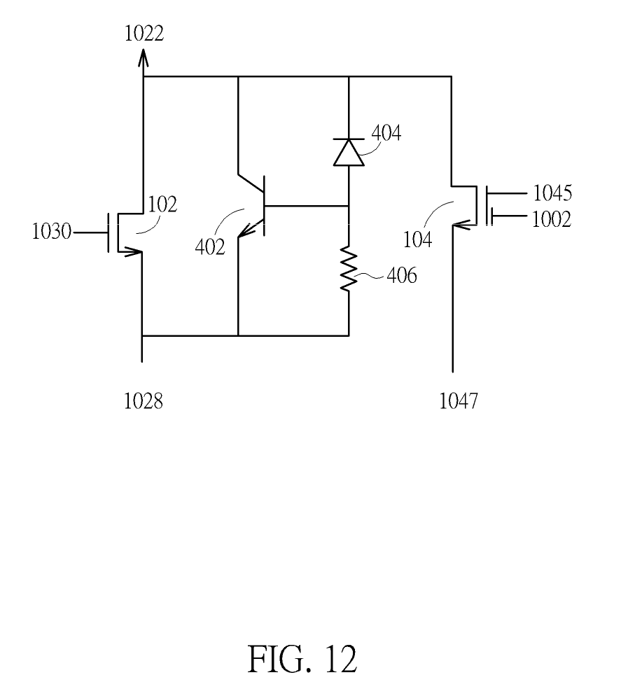

Please refer to FIGS. 10, 11. FIG. 10 is a diagram illustrating a cross section of a VDMOS power device 1000 with high voltage start-up unit according to a third embodiment of the present invention, and FIG. 11 is a diagram illustrating a top view corresponding to FIG. 10. As shown in FIG. 10, a difference between the VDMOS power device 1000 and the VDMOS power device 100 is that the high voltage start-up unit 104 of the VDMOS power device 1000 further includes a first gate 1002, wherein the first gate 1002 is formed within the deep doping well 1041 and on the doping region 1043, and in the VDMOS power device 1000, both the first gate 1002 and the gate 1045 control the two-dimensional direction start-up current 1055. In one embodiment of the present invention, the first gate 1002 is a polysilicon gate. As shown in FIG. 11, the first gate 1002 also has a two-dimensional shape in a top view of the VDMOS power device 1000. That is to say, a two-dimensional shape of the first gate 1002 corresponds to a second concentric circle centered on the well 1053. In addition, subsequent operational principles of the VDMOS power device 1000 are the same as those of the VDMOS power device 100, so further description thereof is omitted for simplicity. In addition, please refer to FIG. 12. FIG. 12 is a diagram illustrating an equivalent circuit corresponding to FIG. 10. As shown in FIG. 12, the high voltage start-up unit 104 of the VDMOS power device 1000 utilizes the first gate 1002 and the gate 1045 to control the two-dimensional direction start-up current 1055 together.

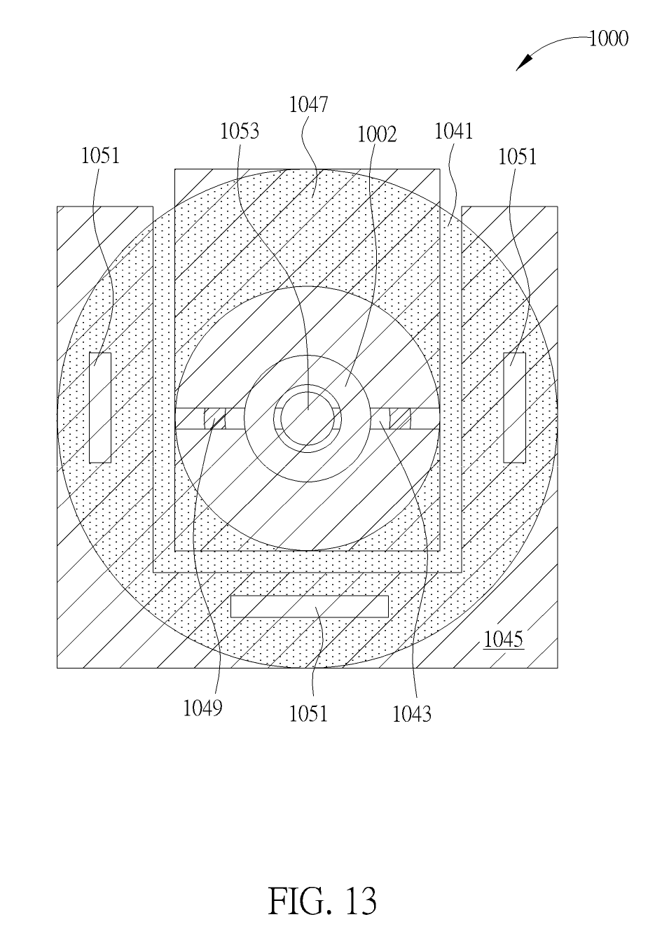

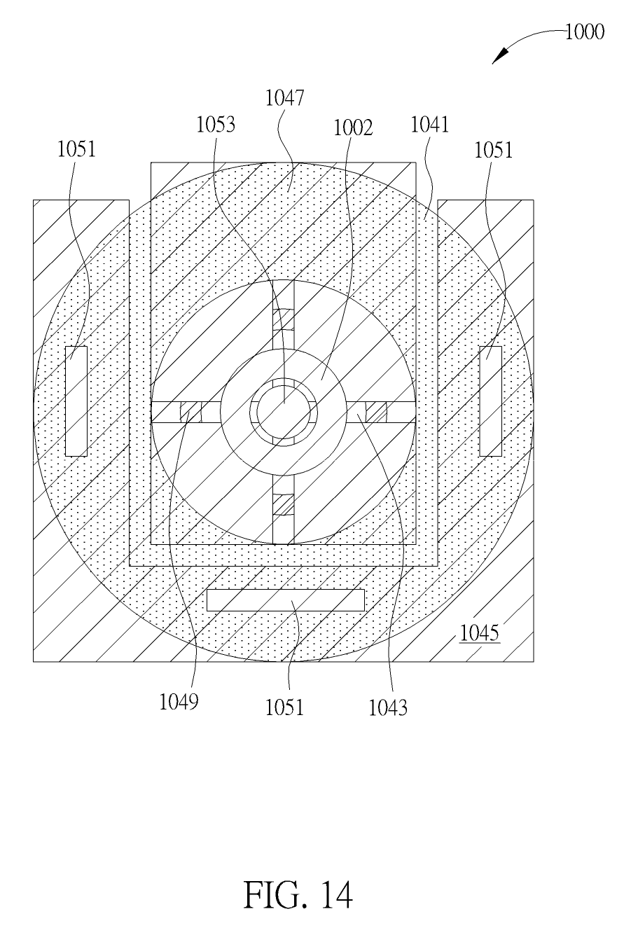

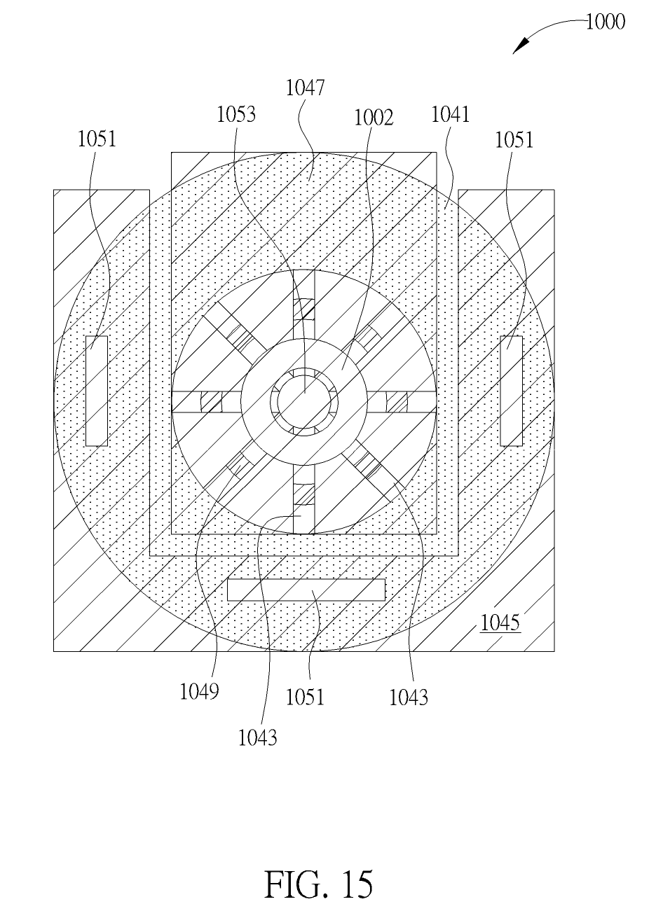

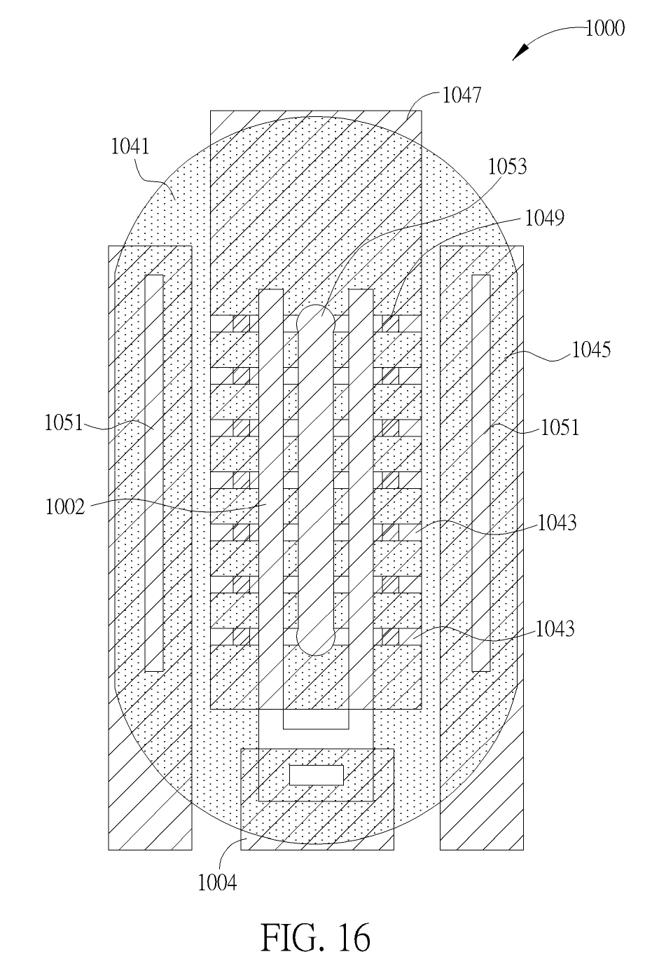

In addition, please refer to FIGS. 13-16. FIGS. 13-16 are diagrams illustrating top views of the VDMOS power device 1000 according to different embodiments of the present invention. As shown in FIGS. 13-15, a difference between FIGS. 13-15 and FIGS. 5-7 is that FIGS. 13-15 further include the first gate 1002, wherein the two-dimensional shape of the first gate 1002 corresponds to the second concentric circle centered on the well 1053. In addition, as shown in FIG. 16, differences between FIG. 16 and FIG. 8 are that FIG. 16 further includes the first gate 1002 and a metal layer electrically connected to the first gate 1002, wherein the two-dimensional shape of the first gate 1002 corresponds to a plurality of second channels which are centered on the well 1053 parallel to the well 1053 (e.g. 2 second channels centered on the well 1053 are parallel to the well 1053), and the plurality of second channels parallel to the well 1053 cross the plurality of first channels centered on the well 1053.

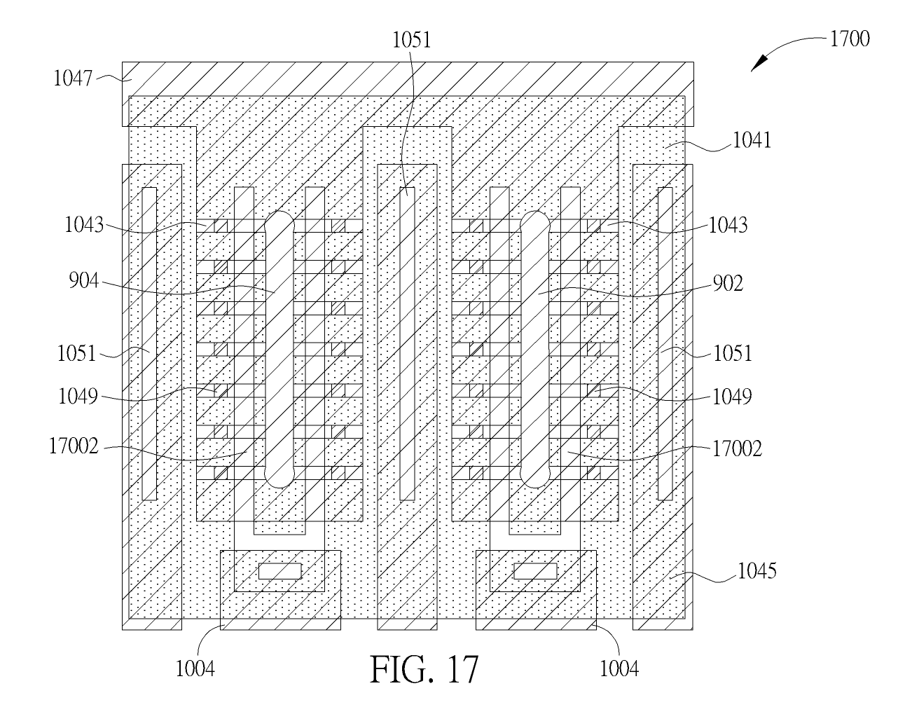

Please refer to FIG. 17. FIG. 17 is a diagram illustrating a top view of a VDMOS power device 1700 with high voltage start-up unit according to a fourth embodiment of the present invention. As shown in FIG. 17, a difference between the VDMOS power device 1700 and the VDMOS power device 900 is that the high voltage start-up unit 104 of the VDMOS power device 1700 further includes a first gate 17002, wherein a two-dimensional shape of the first gate 17002 corresponds to a plurality of second channels centered on each well of the plurality of wells (e.g. the parallel wells 902, 904), wherein the plurality of second channels are parallel to the each well of the plurality of wells. For example, taking the well 902 as an example, the two-dimensional shape of the first gate 17002 corresponds to the plurality of second channels which are centered on the well 902 parallel to the well 902 (e.g. 2 second channels centered on the well 902 are parallel to the well 902), wherein the plurality of second channels parallel to the well 902 cross the plurality of first channels centered on the well 902. In addition, a number of the plurality of wells depends on a requirement of a designer of the VDMOS power device 1700.

In addition, the present invention is not limited to the above mentioned two-dimensional shapes of the high voltage start-up units 104 shown in the VDMOS power devices 100, 900, 1000, 1700. That is to say, any configuration in which the VDMOS power devices 100, 900, 1000, 1700 utilize the high voltage start-up unit 104 to provide the two-dimensional direction start-up current 1055 to predetermined function units of the VDMOS power devices 100, 900, 1000, 1700 falls within the scope of the present invention.

To sum up, the VDMOS power device utilizes a same process to integrate the VDMOS power transistor with the high voltage start-up unit, wherein the high voltage start-up unit can provide the two-dimensional direction start-up current to predetermined function units of the VDMOS power device. Because the high voltage start-up unit can adjust and provide the two-dimensional direction start-up current in a two-dimensional direction, compared to the prior art, the high voltage start-up unit not only has a greater flexibility to adjust the two-dimensional direction start-up current, but can also provide the greater two-dimensional direction start-up current. Therefore, the present invention not only can make the VDMOS power device normally work in a shorter period of time after the VDMOS power device is powered on, but cannot also make the VDMOS power device fail to start up.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A vertical double diffused metal-oxide-semiconductor (VDMOS) power device with high voltage start-up unit, comprising:
a VDMOS power transistor, comprising:
a first metal layer;
a substrate layer with first conductivity type formed on the first metal layer;
an epitaxy layer with first conductivity type formed on the substrate layer;
a second metal layer; and
a plurality of polysilicon layers formed on the epitaxy layer, wherein the second metal layer is formed on the plurality of polysilicon layers and the epitaxy layer; and
the high voltage start-up unit formed on the epitaxy layer, wherein the high voltage start-up unit is used for providing a two-dimensional direction start-up current to the VDMOS power device.

2. The VDMOS power device of claim 1, wherein each polysilicon layer of the plurality of polysilicon layers corresponds to a first oxide layer, a first doping well and a second doping well with second conductivity type, a first doping region and a second doping region with first conductivity type, and a second oxide layer, wherein the first oxide layer is formed on the epitaxy layer, the first doping well and the second doping well are formed within the epitaxy layer, the first doping region and the second doping region are formed within the first doping well and the second doping well respectively, the each polysilicon layer is formed on the first oxide layer, the second oxide layer covers the each polysilicon layer, and the second metal layer is formed on the first doping well, the second doping well, the first doping region, the second doping region, and the second oxide layer.

3. The VDMOS power device of claim 2, wherein the first conductivity type is N type and the second conductivity type is P type.

4. The VDMOS power device of claim 1, wherein the high voltage start-up unit comprises:
a deep doping well with second conductivity type formed within the epitaxy layer, wherein the deep doping well surrounds a well;
a doping region with first conductivity type formed within the deep doping well, wherein the doping region has a two-dimensional shape in a top view of the VDMOS power device;
a gate formed on the deep doping well; and
a source formed on the deep doping well;
wherein the gate is used for controlling the two-dimensional direction start-up current flowing from the first metal layer through the epitaxy layer, the well, and the doping region to the source.

5. The VDMOS power device of claim 4, wherein the two-dimensional shape of the doping region corresponds to a first concentric circle centered on the well in the top view.

6. The VDMOS power device of claim 5, wherein the high voltage start-up unit further comprises:
a first gate formed within the deep doping well and on the doping region, wherein the first gate is used for controlling the two-dimensional direction start-up current, and a two-dimensional shape of the first gate corresponds to a second concentric circle centered on the well in the top view.

7. The VDMOS power device of claim 4, wherein the two-dimensional shape of the doping region corresponds to a plurality of channels centered on the well in the top view.

8. The VDMOS power device of claim 7, wherein the high voltage start-up unit further comprises:
a first gate formed within the deep doping well and on the doping region, wherein the first gate is used for controlling the two-dimensional direction start-up current, and a two-dimensional shape of the first gate corresponds to a second concentric circle centered on the well in the top view.

9. The VDMOS power device of claim 4, wherein a two-dimensional shape of the well corresponds to a strip in the top view, and the two-dimensional shape of the doping region corresponds to a plurality of first channels centered on the well.

10. The VDMOS power device of claim 9, wherein the high voltage start-up unit further comprises:
a first gate formed within the deep doping well and on the doping region, wherein the first gate is used for controlling the two-dimensional direction start-up current, a two-dimensional shape of the first gate corresponds to a plurality of second channels centered on the well in the top view, and the plurality of second channels cross the plurality of first channels in the top view.

11. The VDMOS power device of claim 1, wherein the high voltage start-up unit comprises:
a deep doping well with second conductivity type formed within the epitaxy layer, wherein the deep doping well surrounds a plurality of wells;
a doping region with first conductivity type formed within the deep doping well, wherein the doping region has a two-dimensional shape in a top view of the VDMOS power device;
a gate formed on the deep doping well; and
a source formed on the deep doping well;
wherein the gate is used for controlling the two-dimensional direction start-up current flowing from the first metal layer through the epitaxy layer, the plurality of wells, and the doping region to the source.

12. The VDMOS power device of claim 11, wherein a two-dimensional shape of each well of the plurality of wells corresponds to a strip in the top view, and a two-dimensional shape of the doping region corresponds to a plurality of first channels centered on each well of the plurality of wells.

13. The VDMOS power device of claim 12, wherein the high voltage start-up unit further comprises:
a first gate formed within the deep doping well and on the doping region, wherein the first gate is used for controlling the two-dimensional direction start-up current, a two-dimensional shape of the first gate corresponds to a plurality of second channels centered on each well of the plurality of wells in the top view, and the plurality of second channels cross the plurality of first channels in the top view.

14. The VDMOS power device of claim 1, further comprising:
a field oxide layer formed on the epitaxy layer and between the VDMOS power transistor and the high voltage start-up unit, wherein the field oxide layer is used for making the VDMOS power transistor be isolated from the high voltage start-up unit.

15. The VDMOS power device of claim 14, wherein the field oxide layer is formed through a Local Oxidation of Silicon (LOCOS) method.

16. The VDMOS power device of claim 1, wherein the first metal layer is a drain of the VDMOS power transistor, the plurality of polysilicon layers are a gate of the VDMOS power transistor, and the second metal layer is a source of the VDMOS power transistor.

17. The VDMOS power device of claim 1, wherein ion concentration of the substrate layer is greater than ion concentration of the epitaxy layer.
